(19) United States
(12) Patent Application Publication
(10) Pub. No.: US 2026/0321300 A1
(43) Pub. Date: Oct. 15, 2026

(54) DRIVING VOLTAGE SUPPLYING CIRCUIT FOR NON-VOLATILE MEMORY AND ASSOCIATED CONTROL METHOD

(71) Applicant: eMemory Technology Inc., Hsin-Chu (TW)

(72) Inventors: Wei-Ming KU, Hsinchu County (TW); Tsung-Ta HSIEH, Hsinchu County (TW)

(21) Appl. No.: 19/643,988

(22) Filed: Apr. 10, 2026

Related U.S. Application Data
(60) Provisional application No. 63/788,176, filed on Apr. 14, 2025.

(51) Int. Cl. G11C 5/14; G11C 7/10; H02M 3/07; H03K 19/0185

(52) U.S. Cl. CPC G11C 5/145; G11C 7/1096; H02M 3/07; H03K 19/018521

(57) ABSTRACT

A driving voltage supplying circuit for a non-volatile memory is provided. In the driving voltage supplying circuit, the charge pump is used to generate an erase voltage, and the level shifters are used to transmit the erase voltage. When the non-volatile memory performs the erase action, the level shifters provides the erase voltage to the memory cell array. The present invention further provides a control method for the driving voltage supplying circuit in order to assure that all transistors in the level shifters to be operated in a safe operating area (SOA).

This application claims the benefit of US provisional application Serial No. 63/788,176, filed Apr. 14, 2025, the subject matters of which are incorporated herein by references.

### FIELD OF THE INVENTION

The present invention relates to a voltage supplying circuit, and more particularly to a driving voltage supplying circuit for a non-volatile memory and an associated control method.

### BACKGROUND OF THE INVENTION

Non-volatile memory is widely used in electronic products for its ability to retain data without power. Generally, a non-volatile memory comprises a memory cell array.

Please refer to FIG. 1A, which illustrates a circuit diagram of a conventional memory cell. The memory cell c1 typically includes a select transistor Msel, a floating gate transistor Mf, and an erase capacitor C. As shown in FIG. 1A, these components are connected to a word line WL, a bit line BL, a source line SL, and an erase line EL to facilitate memory operations.

Please refer to FIG. 1B, which illustrates the memory cell array. The memory cells are arranged in a matrix and are often divided into sectors. Specific lines, such as erase lines EL₁ and EL₂, are arranged to control corresponding sectors.

To perform program or erase actions, specific bias voltages must be applied to the aforementioned lines. For instance, a program voltage (V_{PP}) or a high erase voltage (V_{EE}) is required during operation. Therefore, a driving voltage supplying circuit is essential to generate these voltages and selectively provide them to the memory array.

### SUMMARY OF THE INVENTION

An embodiment of the present invention provides a driving voltage supplying circuit. The driving voltage supplying circuit is coupled to a memory cell array of a non-volatile memory. The memory cell array includes a first sector and a second sector. All memory cells in the first sector are connected with a first erase line. All memory cells in the second sector are connected with a second erase line. The driving voltage supplying circuit includes a power circuit and a first level shifter. The power circuit receives a first supply voltage and a second supply voltage. A first output terminal of the power circuit generates a first output voltage. A second output terminal of the power circuit generates a second output voltage. A third output terminal of the power circuit generates a switching output voltage. A high power voltage terminal of the first level shifter is connected with the second output terminal of the power circuit to receive the second output voltage. The second output voltage is a high power voltage of the first level shifter. A bias terminal of the first level shifter is connected with the first output terminal of the power circuit to receive the first output voltage. The first output voltage is a bias voltage of the first level shifter. A low power voltage terminal of the first level shifter is connected with the third output terminal of the power circuit to receive the switching output voltage. The switching output voltage is a low power voltage of the first level shifter. An input terminal of the first level shifter receives a first control signal. An output terminal of the first level shifter outputs a first level shifted signal. The output terminal of the first level shifter is coupled to the first erase line. When an erase action is not performed by the non-volatile memory, the first output voltage of the power circuit is the first supply voltage, the second output voltage is the first supply voltage, and the switching output voltage is the second supply voltage. When the non-volatile memory is in a first transition phase, the first output voltage, the second output voltage and the switching output voltage are adjusted by the power circuit. The non-volatile memory enters an erase phase after the first transition phase. In the erase phase, the first output voltage is adjusted to a program voltage, the second output voltage is increased to an erase voltage, and the switching output voltage is increased to the program voltage. The erase voltage is higher than the program voltage, the program voltage is higher than the first supply voltage. The first supply voltage is higher than the second supply voltage.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit diagram illustrating a memory cell of a non-volatile memory;

FIG. 1B (prior art) is a schematic circuit diagram illustrating a memory cell array of the non-volatile memory;

FIG. 2A is a schematic circuit diagram illustrating a driving voltage supplying circuit according to a first embodiment of the present invention;

FIG. 2B is a schematic circuit diagram illustrating a circuitry structure of a level shifter used in the driving voltage supplying circuit shown in FIG. 2A;

FIG. 3A is a flowchart illustrating the operations of the power circuit in the driving voltage supplying circuit of the first embodiment during the erase action;

FIG. 3B is a schematic timing waveform diagram illustrating associated signals of the driving voltage supplying circuit of the first embodiment during the erase action;

FIGS. 3C-3H are schematic circuit diagrams illustrating the operations of the driving voltage supplying circuit of the first embodiment during the erase action;

FIG. 4A is a schematic circuit diagram illustrating a driving voltage supplying circuit according to a second embodiment of the present invention;

FIG. 4B is a schematic circuit diagram illustrating a circuitry structure of a level shifter used in the driving voltage supplying circuit shown in FIG. 4A;

FIG. 5A is a flowchart illustrating the operations of the power circuit in the driving voltage supplying circuit of the second embodiment during the erase action;

FIG. 5B is a schematic timing waveform diagram illustrating associated signals of the driving voltage supplying circuit of the second embodiment during the erase action; and

FIGS. 5C-5L are schematic circuit diagrams illustrating the operations of the driving voltage supplying circuit of the second embodiment during the erase action.

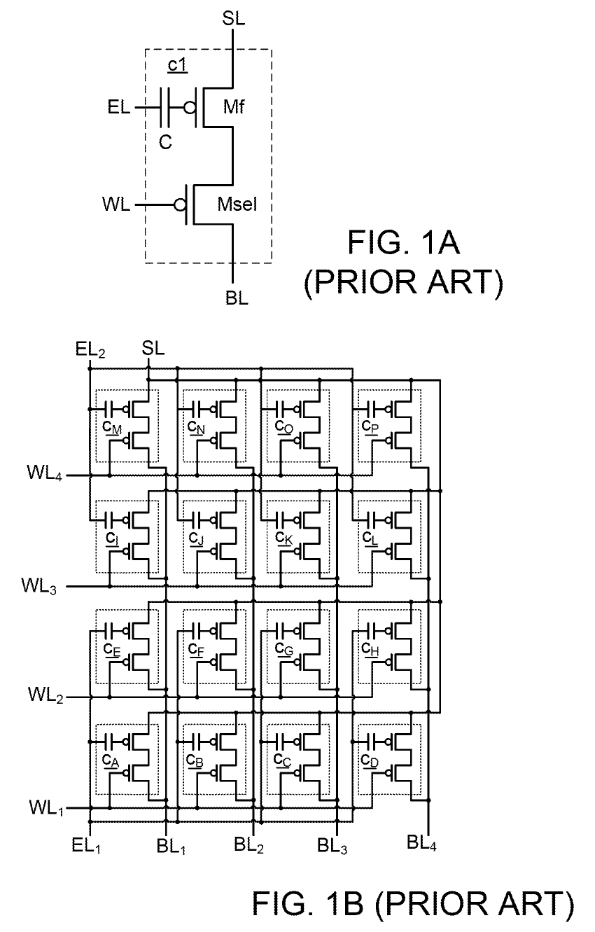

### DETAILED DESCRIPTION OF PREFERRED EMBODIMENTS

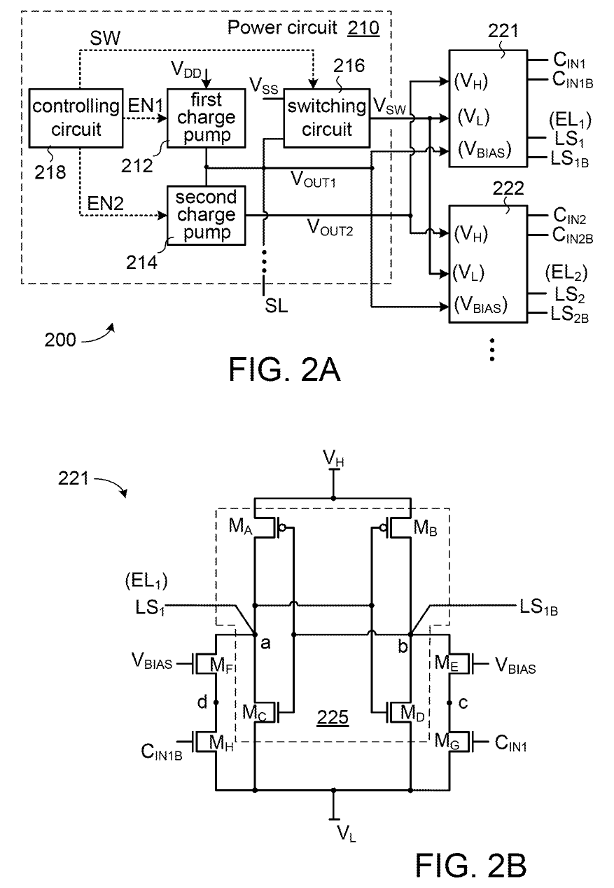

FIG. 2A is a schematic circuit diagram illustrating a driving voltage supplying circuit according to a first embodiment of the present invention. In this embodiment, the driving voltage supplying circuit 200 includes a power circuit 210 and a plurality of level shifters (e.g., two level shifters 221 and 222). The driving voltage supplying circuit 200 can provide a program voltage V_{PP} and an erase voltage V_{EE} to a memory cell array when the non-volatile memory performs a program action and an erases action, respectively.

The power circuit 210 includes a controlling circuit 218, a first charge pump 212, a second charge pump 214, and a switching circuit 216. The power circuit 210 has three output terminals that are connected with all level shifters 221 and 222. The three output terminals of the power circuit 210 includes the output terminal of the first charge pump 212, the output terminal of the second charge pump 214 and the output terminal of the switching circuit 216.

The controlling circuit 218 generates a switching signal SW to control the switching circuit 216. In addition, the controlling circuit 218 generates enable signals EN1 and EN2 to respectively control the first charge pump 212 and the second charge pump 214. When the enable signal EN1 is not activated, the first charge pump 212 is disabled. When the enable signal EN1 is activated, the first charge pump 212 is enabled. When the enable signal EN2 is not activated, the second charge pump 214 is disabled. When the enable signal EN2 is activated, the second charge pump 214 is enabled.

The voltage input terminal of the first charge pump 212 receives a first supply voltage V_{DD}, and the output terminal of the first charge pump 212 outputs a first output voltage V_{OUT1}. When the first charge pump 212 is disabled, the first output voltage V_{OUT1} generated by the first charge pump 212 is equal to the first supply voltage V_{DD}. When the first charge pump 212 is enabled, the first charge pump 212 boosts the received first supply voltage V_{DD} to the first output voltage V_{OUT1} (i.e. a voltage level higher than the first supply voltage V_{DD}) and there is a first ratio relationship between the first output voltage V_{OUT1} and the first supply voltage V_{DD}, wherein the first ratio value is greater than 1. For example, when the first charge pump 212 is enabled, the first supply voltage V_{DD} is 2.5V, and the first output voltage V_{OUT1} is 7.5V. That is, V_{OUT1} = 3×V_{DD}, and the first ratio value is equal to 3.

The voltage input terminal of the second charge pump 214 is connected with the output terminal of the first charge pump 212 to receive the first output voltage V_{OUT1}. The output terminal of the second charge pump 214 outputs a second output voltage V_{OUT2}. When the second charge pump 214 is disabled (e.g., when the second enable signal is not activated), the second charge pump 214 provides a conductive path (for example, controlled by a pass gate signal) such that such that the second output voltage V_{OUT2} generated by the second charge pump 214 is substantially equal to the first output voltage V_{OUT1}. When the second charge pump 214 is enabled, the second charge pump 214 boosts the received first output voltage V_{OUT1} to the second output voltage V_{OUT2} (a voltage level higher than the first supply voltage V_{DD}), and there is a second ratio relationship between the second output voltage V_{OUT2} and the first output voltage V_{OUT1}, wherein the second ratio value is greater than 1. For example, when the first charge pump 212 and the second charge pump 214 are enabled, the first output voltage V_{OUT1} is 7.5V, and the second output voltage V_{OUT2} is 13.875V. That is, V_{OUT2} = 1.85×V_{OUT1}, wherein the second ratio value is equal to 1.85.

The switching circuit 216 receives a second supply voltage V_{SS} and the first output voltage V_{OUT1}. According to the switching signal SW, the output terminal of the switching circuit 216 outputs a switching output voltage V_{SW}. In other words, the switching output voltage V_{SW} is one of the second supply voltage V_{SS} and the first output voltage V_{OUT1}. The first supply voltage V_{DD} is greater than the second supply voltage V_{SS}. For example, the first supply voltage V_{DD} is 2.5V, and the second supply voltage V_{SS} is the ground voltage (0V).

The level shifters 221 and 222 have the same circuitry structure. The high power voltage terminals of the level shifters 221 and 222 are connected with the output terminal of the second charge pump 214 to receive the second output voltage V_{OUT2}. In addition, the second output voltage V_{OUT2} is used as the high power voltage V_{H} of the level shifters 221 and 222. The low power voltage terminals of the level shifters 221 and 222 are connected with the output terminal of the switching circuit 216 to receive the switching output voltage V_{SW}. The switching output voltage V_{SW} is used as a low power voltage V_{L} of the level shifters 221 and 222. The bias terminals of the level shifters 221 and 222 are connected with the output terminal of the first charge pump 212 to receive the first output voltage V_{OUT1}. The first output voltage V_{OUT1} is used as a bias voltage V_{BIAS} of the level shifters 221 and 222.

The input terminal of the level shifter 221 receives a control signal C_{IN1}. The inverting input terminal of the level shifter 221 receives an inverted control signal C_{IN1B}. The output terminal of the level shifter 221 outputs a level shifted signal LS₁. The inverting output terminal of the level shifter 221 generates an inverted level shifted signal LS_{1B}. Similarly, the input terminal of the level shifter 222 receives a control signal C_{IN2}. The inverting input terminal of the level shifter 222 receives an inverted control signal C_{IN2B}. The output terminal of the level shifter 222 outputs a level shifted signal LS₂. The inverting output terminal of the level shifter 222 generates an inverted level shifted signal LS_{2B}.

When the first charge pump 212 is enabled, the first output voltage V_{OUT1} generated by the first charge pump 212 can be used as the program voltage V_{PP}. In other words, the program voltage V_{PP} is equal to the product of the first ratio value and the first supply voltage V_{DD}. Consequently, when the program action is performed, the source line SL of the memory cell array is coupled to the output terminal of the first charge pump 212 to receive the output voltage V_{OUT1}, and the output voltage V_{OUT1} is used as the program voltage V_{PP}. When both the first charge pump 212 and the second charge pump 214 are enabled, the second output voltage V_{OUT2} generated by the second charge pump 214 can be used as the erase voltage V_{EE}. In other words, the erase voltage V_{EE} is equal to the product of the second ratio value and the program voltage V_{PP}.

In the memory cell array of the non-volatile memory, all memory cells in the first sector are connected with the erase line EL₁, and all memory cells in the second sector are connected with the erase line EL₂. Furthermore, the output terminal of the level shifter 221 is coupled to the erase line EL₁, and thus the erase line EL₁ receives the level shifted signal LS₁. Similarly, the output terminal of the level shifter 222 is coupled to the erase line EL₂, and thus the erase line EL₂ receives the level shifted signal LS₂. When the erase action is performed, the erase voltage V_{EE} is selectively provided to the erase lines EL₁ and EL₂ according to the logic levels of the control signals C_{IN1} and C_{IN2}.

For example, if the control signal C_{IN1} is a logic high level (Hi) during the erase action, the level shifted signal LS₁ generated by the level shifter 221 is equal to the erase voltage V_{EE}, and the erase voltage V_{EE} is transmitted to the erase line EL₁. Consequently, all memory cells in the first sector of the memory cell array become the erased state. Furthermore, the control signal C_{IN2} is a logic low level (Lo), and the level shifter 222 does not output the erase voltage V_{EE} to the erase line EL₂. Consequently, the storage states of the memory cells in the second sector of the memory cell array are not changed. For example, the logic high voltage is 2.5V, and the logic low voltage is 0V.

In FIG. 2A, only two level shifters 221 and 222 are shown. It is noted that the number of level shifters in the driving voltage supplying circuit 200 is not shown. For example, in another embodiment, the memory cell array is divided into 16 sectors, the driving voltage supplying circuit 200 includes 16 level shifters. The 16 level shifters are connected with the three output terminals of the power circuit 210. The input terminals of the 16 level shifters receive the corresponding control signals. In addition, the output terminals of the 16 level shifters are respectively coupled to the 16 erase lines.

FIG. 2B is a schematic circuit diagram illustrating a circuitry structure of a level shifter used in the driving voltage supplying circuit shown in FIG. 2A. In an embodiment, the level shifters 221 and 222 are latch-type level shifters. The level shifters 221 and 222 have the same structure. For brevity, only the level shifter 221 will be described as follows. The level shifter 221 includes a latch 225 and transistors M_{E}~M_{H}. In addition, the latch 225 includes transistors M_{A}~M_{D}. In an embodiment, the transistors M_{A} and M_{B} are p-type transistors, and the transistors M_{C}~M_{H} are n-type transistors.

In the latch 225, the first drain/source terminal of the transistor M_{A} is connected with the high power voltage terminal to receive the high power voltage V_{H}, the second drain/source terminal of the transistor M_{A} is connected with the node a, and the gate terminal of the transistor M_{A} is connected with the node b. The first drain/source terminal of the transistor M_{C} is connected with the node a, the second drain/source terminal of the transistor M_{C} is connected with the low power voltage terminal to receive the low power voltage V_{L}, and the gate terminal of the transistor M_{C} is connected with the node b. The first drain/source terminal of the transistor M_{B} is connected with the high voltage power terminal to receive the high power voltage V_{H}, the second drain/source terminal of the transistor M_{B} is connected with the node b, and the gate terminal of the transistor M_{B} is connected with the node a. The first drain/source terminal of the transistor M_{D} is connected with node b, the second drain/source terminal of the transistor M_{D} is connected with the low voltage power terminal to receive the low power voltage V_{L}, and the gate terminal of the transistor M_{D} is connected with node a. Furthermore, the node a is the output terminal of level shifter 221, the voltage at the node a is the level shifted signal LS₁, the node b is the inverting output terminal of level shifter 221, and the voltage at the node b is the inverted level shifted signal LS_{1B}.

The first drain/source terminal of the transistor M_{E} is connected with node b. The second drain/source terminal of the transistor M_{E} is connected with node c. The gate terminal of the transistor M_{E} is connected with the bias terminal to receive the bias voltage V_{BIAS}. The first drain/source terminal of the transistor M_{G} is connected with node c. The second drain/source terminal of the transistor M_{G} is connected with the low power voltage terminal to receive the low power voltage V_{L}. The gate terminal of the transistor M_{G} receives the control signal C_{IN1}. The first drain/source terminal of the transistor M_{F} is connected with node a. The second drain/source terminal of the transistor M_{F} is connected with node d. The gate terminal of the transistor M_{F} is connected with the bias terminal to receive the bias voltage V_{BIAS}. The first drain/source terminal of the transistor M_{H} is connected with the node d. The second drain/source terminal of the transistor M_{H} is connected with the low power voltage terminal to receive the low power voltage V_{L}. The gate terminal of the transistor M_{H} receives the control signal C_{IN1}.

Generally, the transistors M_{A}~M_{H} in the level shifter 221 are manufactured by using a medium voltage device process. Each of the transistors M_{A}~M_{H} can withstand a stress voltage, e.g., 8V. If the voltage difference received by any two terminal of each of the transistors M_{A}~M_{H} is lower than or equal to the stress voltage, the transistors M_{A}~M_{H} can be operated normally. If the voltage difference received by any two terminals of the transistors M_{A}~M_{H} is higher than the stress voltage, the transistors M_{A}~M_{H} may be burned out. In the non-volatile memory, the program voltage V_{PP} is approximately 7V~8V, and the erase voltage V_{EE} is approximately 13~14V. In other words, the program voltage V_{PP} does not exceed the stress voltage of the transistors M_{A}~M_{H}, and the erase voltage V_{EE} exceeds the stress voltage of the transistors M_{A}~M_{H}. For allowing the level shifter 221 to output the erase voltage V_{EE} to the corresponding erase line during the erase action, the controlling circuit 218 in the power circuit 210 controls the first charge pump 212, the second charge pump 214 and the switching circuit 216 to adjust the first output voltage V_{OUT1}, the second output voltage V_{OUT2} and the switching out voltage V_{SW}. Consequently, when the erase action is performed, the level shifter 221 can output the erase voltage V_{EE} to the corresponding erase line.

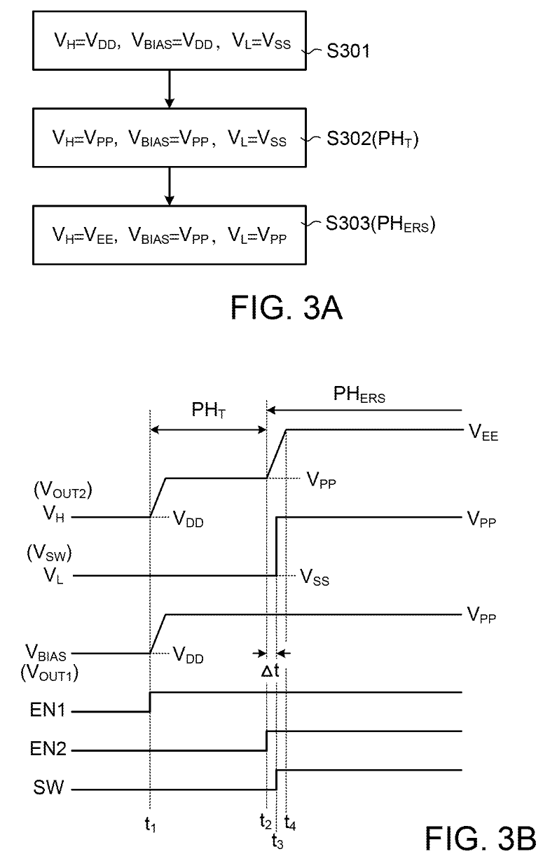

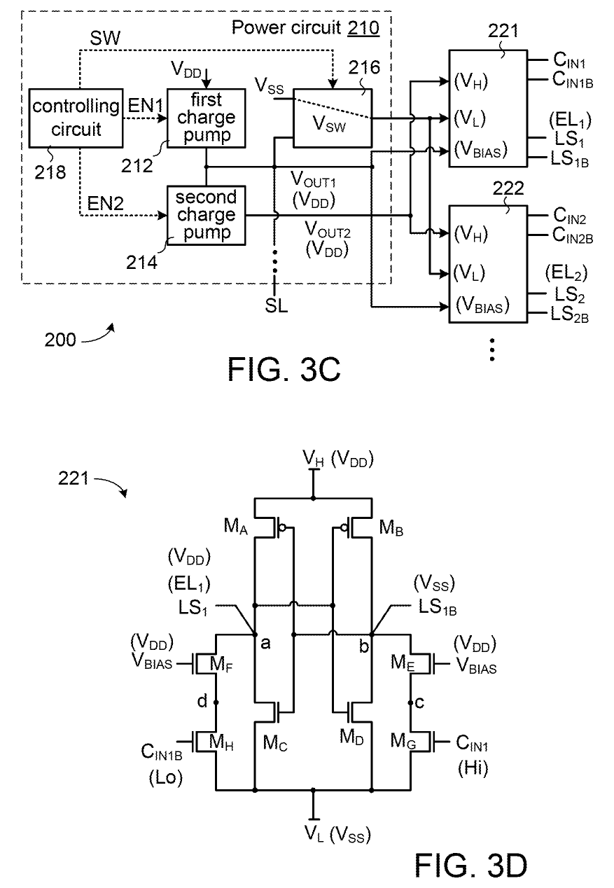

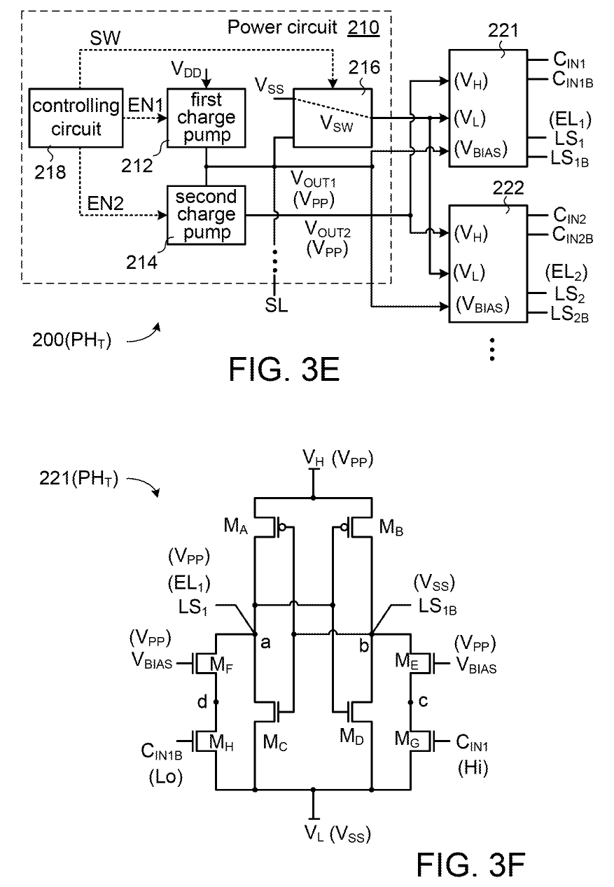

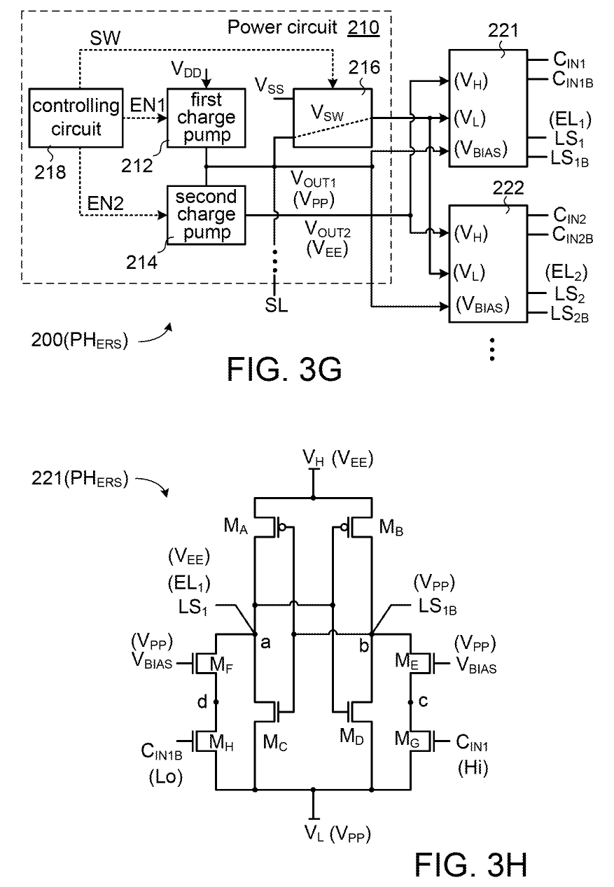

FIG. 3A is a flowchart illustrating the operations of the power circuit in the driving voltage supplying circuit of the first embodiment during the erase action. Firstly, the non-volatile memory has not been subjected to the erase action (Step S301). Meanwhile, the power circuit 210 provides the first supply voltage V_{DD} as the high power voltage V_{H} and the bias voltage V_{BIAS} to the level shifters 221 and 222, and the power circuit 210 provides the second supply voltage V_{SS} as the low power voltage V_{L} to the level shifters 221 and 222.

Then, in a step S302, the non-volatile memory enters a transition phase (PH_{T}). Meanwhile, the power circuit 210 provides the program voltage V_{PP} as the high power voltage V_{H} and the bias voltage V_{BIAS} to the level shifters 221 and 222, and the power circuit 210 provides the second supply voltage V_{SS} as the low power voltage V_{L} to the level shifters 221 and 222.

Then, in a step S303, the non-volatile memory enters an erase phase (PH_{ERS}). Meanwhile, the power circuit 210 provides the erase voltage V_{EE} as the high power voltage V_{H} to the level shifters 221 and 222, and the power circuit 210 provides the program voltage V_{PP} as the low power voltage V_{L} and the bias voltage V_{BIAS} to the level shifters 221 and 222. That is, in the erase phase (PH_{ERS}), at least one of the level shifters 221 and 222 outputs the erase voltage V_{EE}. Consequently, the non-volatile memory can perform the erase action.

FIG. 3B is a schematic timing waveform diagram illustrating associated signals of the driving voltage supplying circuit of the first embodiment during the erase action. FIGS. 3C-3H are schematic circuit diagrams illustrating the operations of the driving voltage supplying circuit of the first embodiment during the erase action.

Please refer to FIGS. 3B, 3C, and 3D. Before the time point t₁, the non-volatile memory has not been subjected to the erase action. The enable signals EN1 and EN2 are not activated by the controlling circuit 218 in the power circuit 210, and the first charge pump 212 and the second charge pump 214 are disabled. Consequently, the first output voltage V_{OUT1} of the first charge pump 212 is equal to the first supply voltage V_{DD}, and the second output voltage V_{OUT2} of the second charge pump 214 is equal to the first supply voltage V_{DD}. Furthermore, the controlling circuit 218 provides the switching signal SW to the switching circuit 216. According to the switching signal SW, the second supply voltage V_{SS} is selected. Consequently, the switching output voltage V_{SW} outputted from the switching circuit 216 is equal to the second supply voltage V_{SS}. In other words, the high voltage power supply terminals of the level shifters 221 and 222 receive the first supply voltage V_{DD}, the low voltage power supply terminals of the level shifters 221 and 222 receive the second supply voltage V_{SS}, and the bias terminals of the level shifters 221 and 222 receive the first supply voltage V_{DD}. In the step S301 of FIG. 3A (i.e., the erase action is not performed), the high power voltage V_{H} is equal to the first supply voltage V_{DD}, the low power voltage V_{L} is equal to the second supply voltage V_{SS}, and the bias voltage V_{BIAS} is equal to the first supply voltage V_{DD}. For example, the first supply voltage V_{DD} is 2.5V, and the second supply voltage V_{SS} is the ground voltage (0V).

As shown in the level shifter 221 of FIG. 3D, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the second supply voltage V_{SS}. Furthermore, the transistor M_{A} is turned on, and the transistor M_{C} is turned off. The voltage at the node a is equal to the first supply voltage V_{DD}. Consequently, the transistor M_{D} is turned on, and the transistor M_{B} is turned off. Since the control signal C_{IN1} is the logic high level (Hi) and the inverted control signal C_{IN1B} is the logic low level (Lo) when the non-volatile memory is not erased, the level shifted signal LS₁ is equal to the first supply voltage V_{DD}, and the inverted level shifted signal LS_{1B} is equal to the second supply voltage V_{SS}.

Similarly, when the control signal C_{IN1} is the logic low level (Lo) and the inverted control signal C_{IN1B} is the logic high level (Hi), the level shifted signal LS₁ is equal to the second supply voltage V_{SS}, and the inverted level shifted signal LS_{1B} is equal to the first supply voltage V_{DD}.

Please refer to FIGS. 3B, 3E and 3F. The time interval between the time point t₁ and the time point t₂ is the transition phase PH_{T}. Before the erase action of the non-volatile memory is performed, the transition phase PH_{T} is required. In the transition phase PH_{T}, the controlling circuit 218 in the power circuit 210 activates the enable signal EN1 but does not activate the enable signal EN2. The first charge pump 212 is enabled, but the second charge pump 214 is disabled. Consequently, the first output voltage V_{OUT1} outputted from the first charge pump 212 rises from the first supply voltage V_{DD} to the program voltage V_{PP}, and the second output voltage V_{OUT2} outputted from the second charge pump 214 also rises from the first supply voltage V_{DD} to the program voltage V_{PP}. Furthermore, the controlling circuit 218 provides the switching signal SW to the switching circuit 216. According to the switching signal SW, the second supply voltage V_{SS} is selected. Consequently, the switching output voltage V_{SW} outputted from the switching circuit 216 is equal to the second supply voltage V_{SS}. In other words, the high voltage power supply terminals of the level shifters 221 and 222 receive the program voltage V_{PP}, the low voltage power supply terminals of the level shifters 221 and 222 receive the second supply voltage V_{SS}, and the bias terminals of the level shifters 221 and 222 receive the program voltage V_{PP}. In the step S302 of FIG. 3A (i.e., in the transition phase PH_{T}), the high power voltage V_{H} is equal to the program voltage V_{PP}, the low power voltage V_{L} is equal to the second supply voltage V_{SS}, and the bias voltage V_{BIAS} is equal to the program voltage V_{PP}. For example, when the first charge pump 212 is enabled, the product of first ratio value and the first supply voltage V_{DD} is equal to the program voltage V_{PP}, and the program voltage V_{PP} is 7.5V.

As shown in the level shifter 221 of FIG. 3F, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the second supply voltage V_{SS}. Furthermore, the transistor M_{A} is turned on, and the transistor M_{C} is turned off. The voltage at the node a is equal to the program voltage V_{PP}. Consequently, the transistor M_{D} is turned on, and the transistor M_{B} is turned off. Since the control signal C_{IN1} is the logic high level (Hi) and the inverted control signal C_{IN1B} is the logic low level (Lo), the level shifted signal LS₁ is equal to the program voltage V_{PP}, and the inverted level shifted signal LS_{1B} is equal to the second supply voltage V_{SS}. Similarly, when the control signal C_{IN1} is the logic low level (Lo) and the inverted control signal C_{IN1B} is the logic high level (Hi), the level shifted signal LS₁ is equal to the second supply voltage V_{SS}, and the inverted level shifted signal LS_{1B} is equal to the program voltage V_{PP}.

As can be seen from FIGS. 3E and 3F, when the non-volatile memory is in the transition phase PH_{T}, the power circuit 210 adjusts the first output voltage V_{OUT1}, the second output voltage V_{OUT2} and the switching output voltage V_{SW}. Furthermore, under control of the power circuit 210, the high power voltage V_{H} received by the level shifters 221 and 222 is higher than the low power voltage V_{L}, and the high power voltage V_{H} minus the low power voltage V_{L} is lower than or equal to the stress voltage. Consequently, all transistors M_{A}~M_{H} can be operated normally without being damaged.

Please refer to FIGS. 3B, 3G and 3H. The time interval after the time point t₂ is the erase phase PH_{ERS}. In the erase phase PH_{ERS}, the non-volatile memory perform the erase actions. The controlling circuit 218 in the power circuit 210 activates the enable signal EN1 and the enable signal EN2. The first charge pump 212 and the second charge pump 214 are enabled. Consequently, the first output voltage V_{OUT1} outputted from the first charge pump 212 is the program voltage V_{PP}, and the second output voltage V_{OUT2} outputted from the second charge pump 214 rises from the program voltage V_{PP} to the erase voltage V_{EE}. At the time point t₃, the controlling circuit 218 provides the switching signal SW to the switching circuit 216. According to the switching signal SW, the switching output voltage V_{SW} outputted from the switching circuit 216 is equal to the program voltage V_{PP}.

In accordance with the present invention, the time difference Δt between the time point t2 and the time point t3 is set to be greater than zero. Consequently, the high power supply voltage V_{H} can be greater than the low power supply voltage V_{H}, a voltage difference between the high power voltage V_{H} and the low power voltage V_{L} is higher than the threshold voltage of the transistors M_{A}~M_{H}, and the storage data of the latch 225 will not be changed. Consequently, the high voltage power supply terminals of the level shifters 221 and 222 receive the erase voltage V_{EE}, and the low voltage power supply terminals and bias terminals of the level shifters 221 and 222 receive the program voltage V_{PP}.

In the step S303 of FIG. 3A (i.e., in the erase phase PH_{ERS}), the high power voltage V_{H} is equal to the erase voltage V_{EE}, the low power voltage V_{L} is equal to the program voltage V_{PP}, and the bias voltage V_{BIAS} is equal to the program voltage V_{PP}. For example, when the first charge pump 212 and the second charge pump 214 are enabled, the product of the second ratio value and the program voltage V_{PP} is equal to the erase voltage V_{EE}, and the erase voltage V_{EE} is 13.875V.

As shown in FIG. 3H, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the program voltage V_{PP}. Furthermore, the transistor M_{A} is turned on, and the transistor M_{C} is turned off. The voltage at the node a is equal to the erase voltage V_{EE}. Consequently, the transistor M_{D} is turned on, and the transistor M_{B} is turned off. Since the control signal C_{IN1} is the logic high level (Hi) and the inverted control signal C_{IN1B} is the logic low level (Lo), the level shifted signal LS₁ is equal to the erase voltage V_{EE}, and the inverted level shifted signal LS_{1B} is equal to the program voltage V_{PP}.

Similarly, when the control signal C_{IN1} is the logic low level (Lo) and the inverted control signal C_{IN1B} is the logic high level (Hi), the level shifted signal LS₁ is equal to the program voltage V_{PP}, and the inverted level shifted signal LS_{1B} is equal to the erase voltage V_{EE}.

As can be seen from FIGS. 3B, 3C and 3H, in the erase phase PH_{ERS}, the voltages outputted from the output terminals of the level shifters 221 and 222 of the driving voltage supplying circuit 200 can reach the erase voltage V_{EE}. Furthermore, in the transition phase PH_{T} and the erase phase PH_{ERS}, if the control signal C_{IN1} is continuously maintained in the logic high level (Hi), the waveform change of the level shifted signal LS₁ will be the same as the waveform change of the high power supply voltage V_{H}. Whereas, if the control signal C_{IN1} is continuously maintained the logic low level (Lo), the waveform change of the level shifted signal LS₁ will be the same as the waveform change of the low power supply voltage V_{L}.

Furthermore, at the time point t₄ in the erase phase PH_{ERS}, it can be determined that one of the output terminals of the level shifters 221 and 222 of the driving voltage supplying circuit 200 can provide the erase voltage V_{EE}. In other words, after the time point t₄, the non-volatile memory can start the erase action.

For example, when the erase action is performed, the control signal C_{IN1} is the logic high level (Hi), and the control signal C_{IN}₂ is the logic low level (Lo). Consequently, the level shifted signal LS₁ from the level shifter 221 is the erase voltage V_{EE} and transmitted to the erase line EL₁, and the level shifted signal LS₂ from the level shifter 222 is the program voltage V_{PP} and transmitted to the erase line EL₂. That is, in the memory cell array, the erase line EL₁ receives the erase voltage V_{EE}, and the erase line EL₂ receives the program voltage V_{PP} that is lower than the erase voltage V_{EE}. Consequently, in the memory cell array, all memory cells in the first sector become the erased state, and the storage states of the memory cells in the second sector are kept unchanged.

In the driving voltage supplying circuit 200 of the first embodiment, the second output voltage V_{OUT2} can be increased to the erase voltage V_{EE} and used as the high power supply voltage V_{H} of the level shifters 221 and 222 after only a single transition phase P_{HT}. At the same time, the first output voltage V_{OUT1} is increased to the program voltage V_{PP} and used as the low power supply voltage V_{L} of the level shifters 221 and 222. Furthermore, since the high power voltage V_{H} minus the low power voltage V_{L} is lower than or equal to the stress voltage, all transistors M_{A}~M_{H} can be operated normally without being damaged. It is noted that multiple transition phases can be used to gradually increase the first output voltage V_{OUT1}, the second output voltage V_{OUT2}and the switching output voltage V_{SW}.

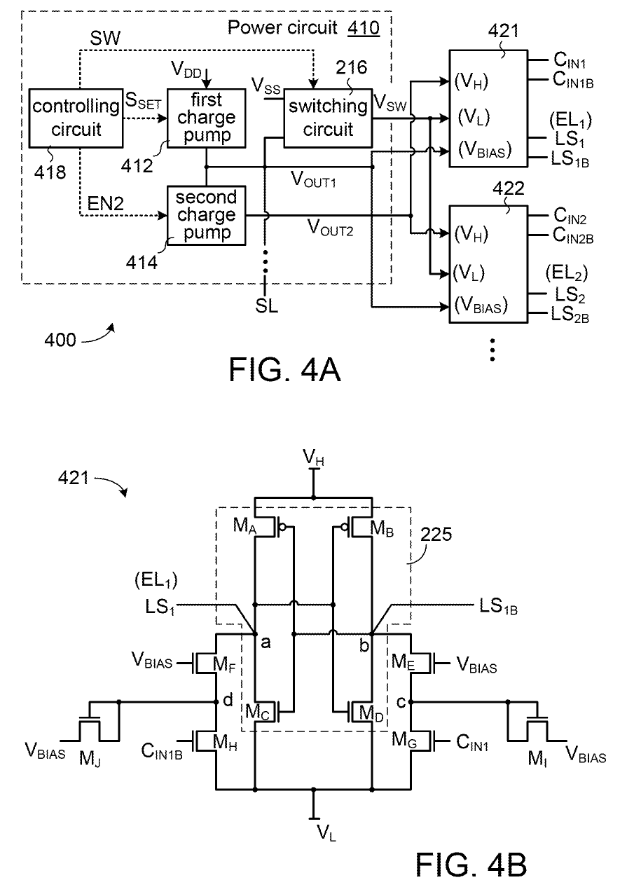

FIG. 4A is a schematic circuit diagram illustrating a driving voltage supplying circuit according to a second embodiment of the present invention. In this embodiment, the driving voltage supplying circuit 400 includes a power circuit 410 and two level shifters 421 and 422. The driving voltage supplying circuit 400 can provide a program voltage V_{PP} and an erase voltage V_{EE} to a memory cell array when the non-volatile memory performs a program action and an erases action, respectively.

The power circuit 410 includes a controlling circuit 418, a first charge pump 412, a second charge pump 414, and a switching circuit 216. The controlling circuit 418 generates a voltage setting signal S_{SET} to control the first charge pump 412 to generate a first output voltage V_{OUT1}. The controlling circuit 418 generates a switching signal SW to control the switching circuit 216. The controlling circuit 418 generates an enable signal EN2 to control the second charge pump 414.

The voltage input terminal of the first charge pump 412 receives a first supply voltage V_{DD}. Moreover, there is no specified relationship between the first output voltage V_{OUT1} of the first charge pump 412 and the first supply voltage V_{DD}. The first output voltage V_{OUT1} outputted from the first charge pump 412 is determined according to the voltage setting signal S_{SET}. For example, according to the voltage setting signal S_{SET}, the first output voltage V_{OUT1} outputted from the first charge pump 412 is set to be in the range between the first supply voltage V_{DD} and the program voltage V_{PP}. That is, the first output voltage V_{OUT1} is higher than or equal to the first supply voltage V_{DD}, and the first output voltage V_{OUT1} is lower than or equal to the program voltage V_{PP}.

The voltage input terminal of the second charge pump 414 is connected with the output terminal of the first charge pump 212 to receive the first output voltage V_{OUT1}. When the second charge pump 414 is enabled, the second charge pump 414 will boost the received first output voltage V_{OUT1} to the second output voltage V_{OUT2}, and there is a ratio relationship between the second output voltage V_{OUT2} and the first output voltage V_{OUT1}, wherein the ratio value R is greater than 1. For example, the second output voltage V_{OUT2} is equal to the ratio value R multiplied by the first output voltage V_{OUT1}, and the ratio value R is equal to 1.85. Furthermore, When the second charge pump 414 is disabled, the second output voltage V_{OUT2} generated by the second charge pump 414 is kept unchanged.

The switching circuit 216 receives a second supply voltage V_{SS} and the first output voltage V_{OUT1}. According to the switching signal SW, the output terminal of the switching circuit 216 generates a switching output voltage V_{SW}. In other words, the switching output voltage V_{SW} is one of the second supply voltage V_{SS} and the first output voltage V_{OUT1}.

In accordance with the present invention, the first output voltage V_{OUT1} is set according to the voltage setting signal S_{SET}, such that a first voltage difference between the second output voltage V_{OUT2} and the switching output voltage V_{SW} is less than or equal to a second voltage difference between a stress voltage and a threshold voltage of the transistors in the level shifter 421 and 422.

The level shifters 421 and 422 have the same circuitry structure. The high power voltage terminals of the level shifters 421 and 422 are connected with the output terminal of the second charge pump 414 to receive the second output voltage V_{OUT2}. In addition, the second output voltage V_{OUT2} is used as the high power voltage V_{H} of the level shifters 421 and 422. The low power voltage terminals of the level shifters 421 and 422 are connected with the output terminal of the switching circuit 216 to receive the switching output voltage V_{SW}. The switching output voltage V_{SW} is used as a low power voltage V_{L} of the level shifters 421 and 422. The bias terminals of the level shifters 421 and 422 are connected with the output terminal of the first charge pump 212 to receive the first output voltage V_{OUT1}. The first output voltage V_{OUT1} is used as a bias voltage V_{BIAS} of the level shifters 421 and 422.

The input terminal of the level shifter 421 receives a control signal C_{IN1}. The inverting input terminal of the level shifter 421 receives an inverted control signal C_{IN1B}. The output terminal of the level shifter 421 generates a level shifted signal LS₁. The inverting output terminal of the level shifter 421 generates an inverted level shifted signal LS_{1B}. Similarly, the input terminal of the level shifter 422 receives a control signal C_{IN2}. The inverting input terminal of the level shifter 422 receives an inverted control signal C_{IN2B}. The output terminal of the level shifter 422 outputs a level shifted signal LS₂. The inverting output terminal of the level shifter 422 generates an inverted level shifted signal LS_{2B}.

In the memory cell array of the non-volatile memory, all memory cells in the first sector are connected with the erase line EL₁, and all memory cells in the second sector are connected with the erase line EL₂. Furthermore, the output terminal of the level shifter 421 is coupled to the erase line EL₁, and the output terminal of the level shifter 422 is coupled to the erase line EL₂. When the erase action is performed, the erase voltage V_{EE} is selectively provided to the erase lines EL₁ and EL₂ according to the logic levels of the control signals C_{IN1} and C_{IN2}.

For example, during the erase action, the control signal C_{IN1} is the logic high level (Hi), and the control signal C_{IN2} is the logic low level (Lo). In the driving voltage supplying circuit 400, the level shifter 421 outputs the erase voltage V_{EE} to the erase line EL₁, but the level shifter 422 does not output the erase voltage V_{EE} to the erase line EL₂. Consequently, all memory cells in the first sector of the memory cell array become the erased state, and the storage states of the memory cells in the second sector of the memory cell array are not changed.

FIG. 4B is a schematic circuit diagram illustrating a circuitry structure of a level shifter used in the driving voltage supplying circuit shown in FIG. 4A. For example, the level shifters 421 and 422 are latch-type level shifters. In addition, the level shifters 421 and 422 have the same structure. When compared with the level shifter 221 of the first embodiment, the level shifter 421 of the second embodiment further includes two transistors M_{I}and M_{J}. The transistors M_{I}and M_{J} are n-type transistors. For brevity, only the connection relationships between the transistors M_{I}and M_{J} and associated transistors will be described as follows.

The first drain/source terminal of the transistor M_{I} is connected with node c. The second drain/source terminal of the transistor M_{I} is connected with the bias terminal to receive the bias voltage V_{BIAS}. The gate terminal of the transistor M_{I} is connected with node c. The first drain/source terminal of the transistor M_{J} is connected with node d. The second drain/source terminal of the transistor M_{J} is connected with the bias terminal to receive the bias voltage V_{BIAS}. The gate terminal of the transistor M_{J} is connected with node d.

Similarly, the transistors M_{A}~M_{J} in the level shifter 421 are manufactured by using a medium voltage device process. Each of the transistors M_{A}~M_{J} can withstand a stress voltage, e.g., 8V. The program voltage V_{PP} is approximately 7V~7.5V. The erase voltage V_{EE} is approximately 12~14V. In other words, the program voltage V_{PP} does not exceed the stress voltage of the transistors M_{A}~M_{J}, and the erase voltage V_{EE} exceeds the stress voltage of the transistors M_{A}~M_{J}.

As known, it is important to allow the level shifter 421 to output the erase voltage V_{EE} to the corresponding erase line during the erase action and allow all transistors M_{A}~M_{J} to be operated in a safe operating area (SOA). For achieving the above purposes, the controlling circuit 418 in the power circuit 410 controls the first charge pump 412, the second charge pump 414 and the switching circuit 216. Consequently, when the erase action is performed, the level shifter 421 can output the erase voltage V_{EE} to the corresponding erase line, and the transistors M_{A}~M_{J} can be operated in the SOA.

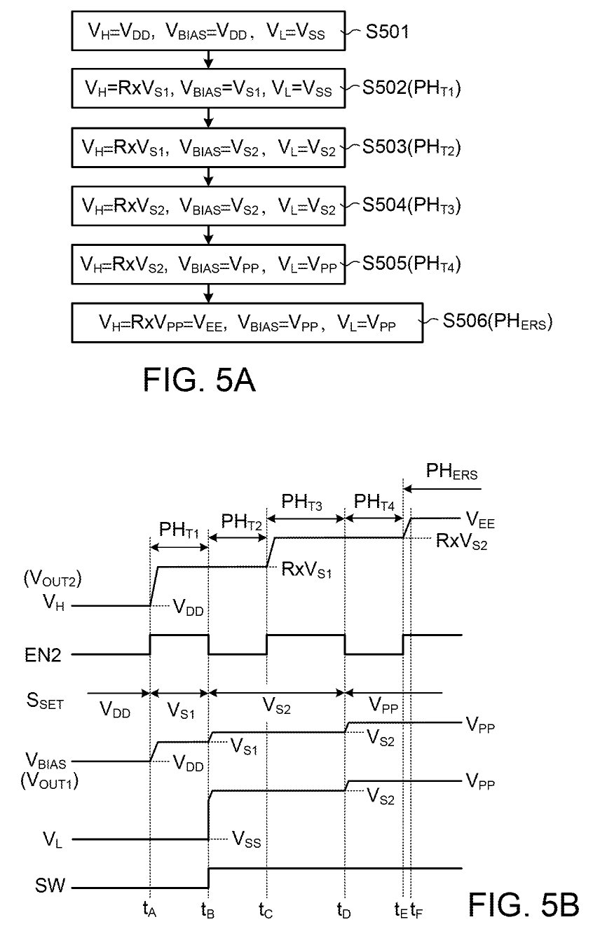

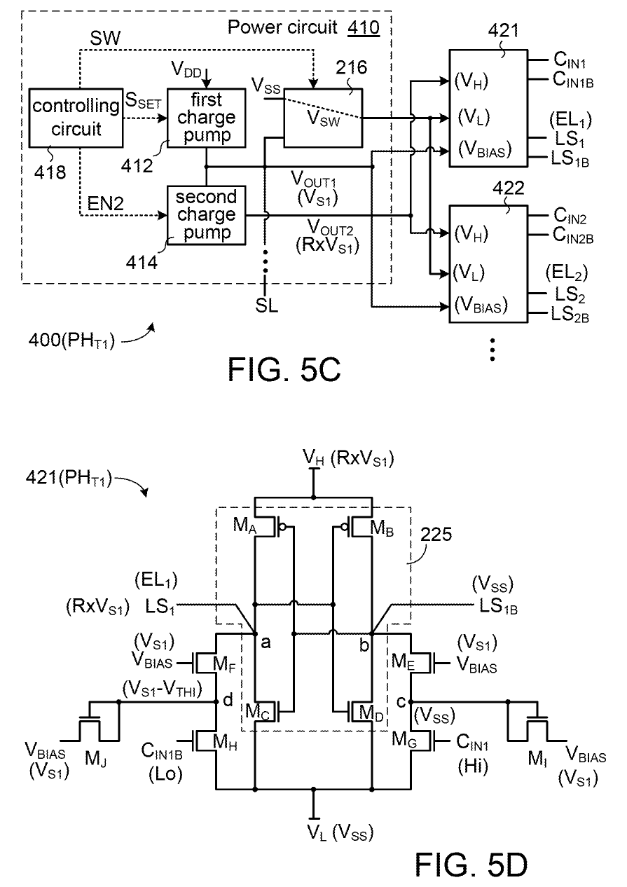

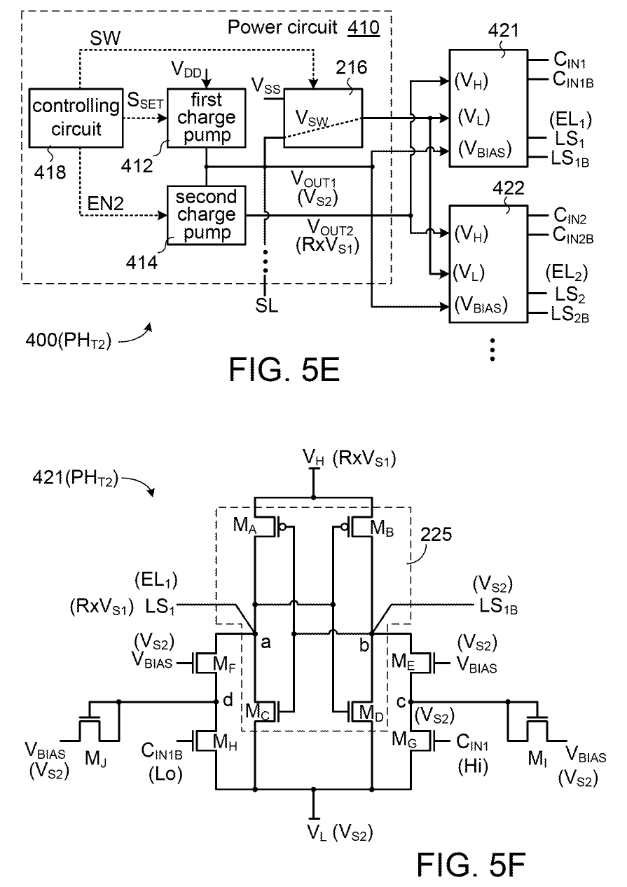

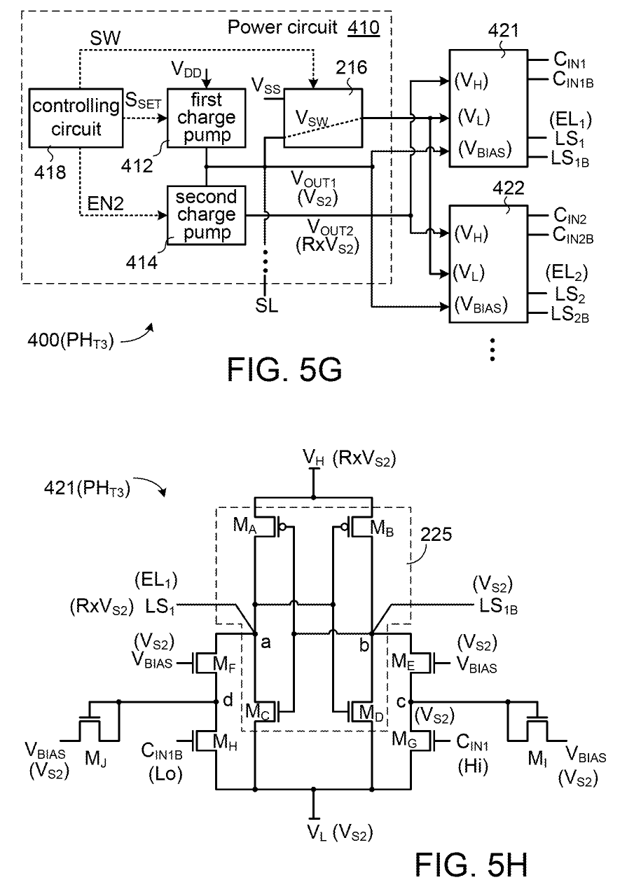

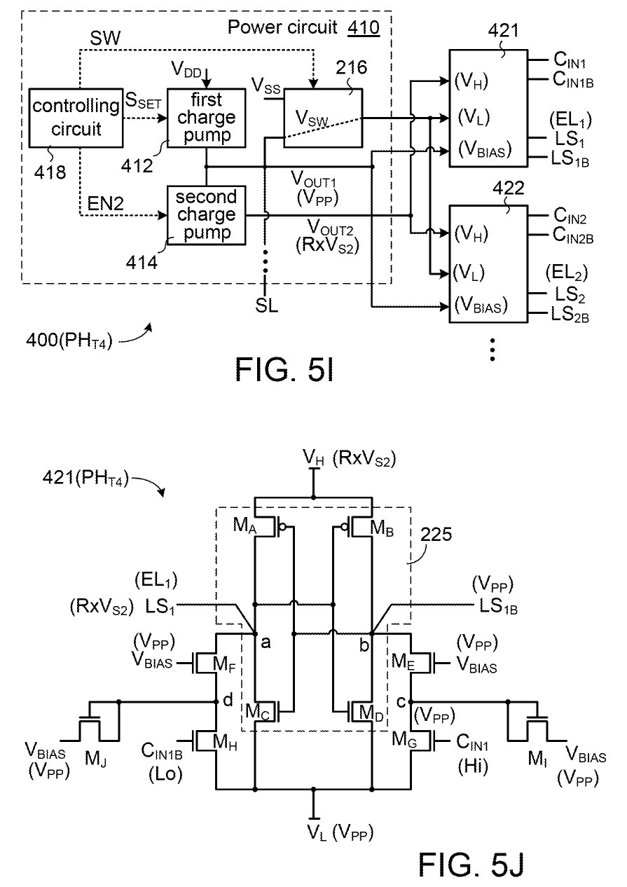

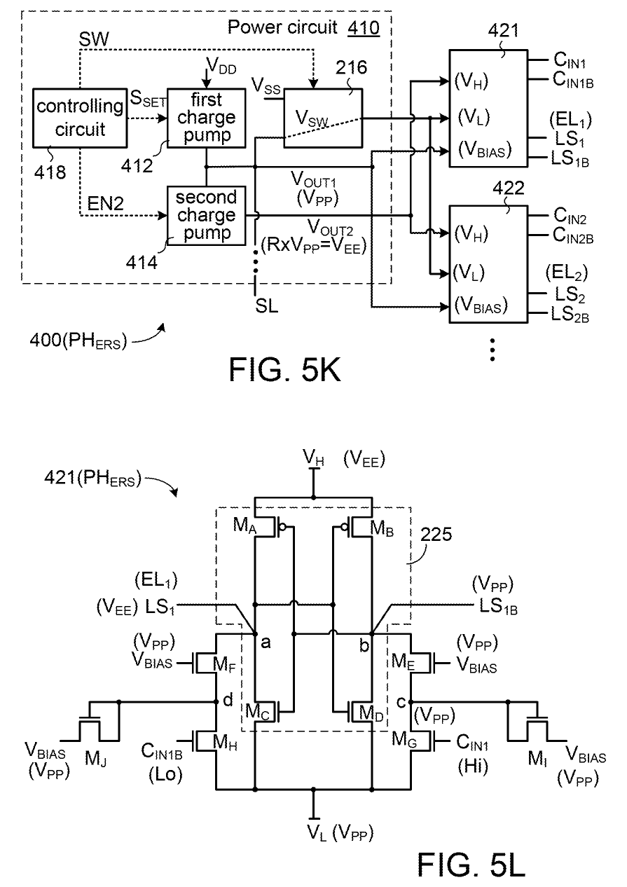

FIG. 5A is a flowchart illustrating the operations of the power circuit in the driving voltage supplying circuit of the second embodiment during the erase action. Firstly, the non-volatile memory has not been subjected to the erase action (Step S501). Meanwhile, the power circuit 410 provides the first supply voltage V_{DD} as the high power voltage V_{H} and the bias voltage V_{BIAS} to the level shifters 421 and 422, and the power circuit 410 provides the second supply voltage V_{SS} as the low power voltage V_{L} to the level shifters 421 and 422.

Then, in a step S502, the non-volatile memory enters a first transition phase (PH_{T}₁). Meanwhile, the first output voltage V_{OUT1} provided by the power circuit 410 is equal to a first set voltage V_{S1}, wherein the first set voltage V_{S1} is higher than the first supply voltage V_{DD}. That is, the power circuit 410 provides the first set voltage V_{S1} as the bias voltage V_{BIAS} to the level shifters 421 and 422. The second output voltage V_{OUT2} provided by the power circuit 410 is equal to the product of the ratio value R and the first set voltage V_{S1}. In other words, the power circuit 410 provides the second output voltage V_{OUT2} (R×V_{S1}) as the high power voltage V_{H} of the level shifters 421 and 422. Furthermore, the power circuit 410 provides the second supply voltage V_{SS} as the switching output voltage V_{SW}. In other words, the power circuit 410 provides the second supply voltage V_{SS} as the low power voltage V_{L} to the level shifters 421 and 422.

Then, in a step S503, the non-volatile memory enters a second transition phase (PH_{T}₂). Meanwhile, the first output voltage V_{OUT1} provided by the power circuit 410 is equal to a second set voltage V_{S}₂, wherein the second set voltage V_{S}₂is higher than the first set voltage V_{S1}. That is, the power circuit 410 provides the second set voltage V_{S}₂ as the bias voltage V_{BIAS} to the level shifters 421 and 422. The second output voltage V_{OUT2} provided by the power circuit 410 is equal to the product of the ratio value R and the first set voltage V_{S1}. In other words, the power circuit 410 provides the second output voltage V_{OUT2} (R×V_{S1}) as the high power voltage V_{H} of the level shifters 421 and 422. Furthermore, the power circuit 410 provides the second set voltage V_{S}₂ as the switching output voltage V_{SW}. In other words, the power circuit 410 provides the second set voltage V_{S}₂ as the low power voltage V_{L} to the level shifters 421 and 422.

Then, in a step S504, the non-volatile memory enters a third transition phase (PH_{T}₃). Meanwhile, the first output voltage V_{OUT1} provided by the power circuit 410 is equal to the second set voltage V_{S}₂. That is, the power circuit 410 provides the second set voltage V_{S}₂ as the bias voltage V_{BIAS} to the level shifters 421 and 422. The second output voltage V_{OUT2} provided by the power circuit 410 is equal to the product of the ratio value R and the second set voltage V_{S}₂. In other words, the power circuit 410 provides the second output voltage V_{OUT2} (R×V_{S}₂) as the high power voltage V_{H} of the level shifters 421 and 422. Furthermore, the power circuit 410 provides the second set voltage V_{S}₂ as the switching output voltage V_{SW}. In other words, the power circuit 410 provides the second set voltage V_{S}₂ as the low power voltage V_{L} to the level shifters 421 and 422.

Then, in a step S505, the non-volatile memory enters a fourth transition phase (PH_{T}₄). Meanwhile, the first output voltage V_{OUT1} provided by the power circuit 410 is equal to the program voltage V_{PP}, wherein the program voltage V_{PP} is higher than the second set voltage V_{S}₂. That is, the power circuit 410 provides the program voltage V_{PP} as the bias voltage V_{BIAS} to the level shifters 421 and 422. The second output voltage V_{OUT2} provided by the power circuit 410 is equal to the product of the ratio value R and the second set voltage V_{S}₂. In other words, the power circuit 410 provides the second output voltage V_{OUT2} (R×V_{S}₂) as the high power voltage V_{H} of the level shifters 421 and 422. Furthermore, the power circuit 410 provides the program voltage V_{PP} as the switching output voltage V_{SW}. In other words, the power circuit 410 provides the program voltage V_{PP} as the low power voltage V_{L} to the level shifters 421 and 422.

Then, in a step S506, the non-volatile memory enters an erase phase (PH_{ERS}). Meanwhile, the first output voltage V_{OUT1} provided by the power circuit 410 is equal to the program voltage V_{PP}. That is, the power circuit 410 provides the program voltage V_{PP} as the bias voltage V_{BIAS} to the level shifters 421 and 422. The second output voltage V_{OUT2} provided by the power circuit 410 is equal to the product of the ratio value R and the program voltage V_{PP} and is also equal to the erase voltage V_{EE}. In other words, the power circuit 410 provides the second output voltage V_{OUT2} (V_{EE}) as the high power voltage V_{H} of the level shifters 421 and 422. Furthermore, the power circuit 410 provides the program voltage V_{PP} as the switching output voltage V_{SW}. In other words, the power circuit 410 provides the program voltage V_{PP} as the low power voltage V_{L} to the level shifters 421 and 422.

FIG. 5B is a schematic timing waveform diagram illustrating associated signals of the driving voltage supplying circuit of the second embodiment during the erase action. FIGS. 5C-5L are schematic circuit diagrams illustrating the operations of the driving voltage supplying circuit of the second embodiment during the erase action.

Before the time point t_{A}, the non-volatile memory has not been subjected to the erase action. The associated signals of the driving voltage supplying circuit 400 and the operations of the level shifter 421 are similar to those of FIGS. 3C and 3D, and not redundantly described herein.

Please refer to FIGS. 5B, 5C and 5D. The time interval between the time point t_{A} and the time point t_{B} is the first transition phase PH_{T}₁. The controlling circuit 418 provides the voltage setting signal S_{SET} to control the first charge pump 412 to generate the first set voltage V_{S1}. That is, the first output voltage V_{OUT1}is equal to the first set voltage V_{S1}. In the first transition phase PH_{T}₁, the controlling circuit 418 activates the enable signal EN2. Consequently, the second output voltage V_{OUT2} provided by the power circuit 410 is equal to the product of the ratio value R and the first set voltage V_{S1}(R×V_{S1}). Furthermore, the controlling circuit 418 provides the switching signal SW to the switching circuit 216. According to the switching signal SW, the switching circuit 216 generates the switching output voltage V_{SW}. The switching output voltage V_{SW} is equal to the second supply voltage V_{SS}. In other words, the high voltage power supply terminals of the level shifters 421 and 422 receive the second output voltage V_{OUT2} (R×V_{S1}). The low voltage power supply terminals of the level shifters 421 and 422 receive the second supply voltage V_{SS}. The bias terminals of the level shifters 421 and 422 receive the first set voltage V_{S1}. For example, the first set voltage V_{S1} is 4.2V, and the ratio value R is 1.85. Consequently, the high power voltage V_{H} is 7.77V (1.85×4.2V), the bias voltage V_{BIAS} is 4.2V, and the low power voltage V_{L} is 0V (V_{SS}). Obviously, the voltage difference (7.77V) between the high power voltage V_{H} and the low power voltage V_{L} is higher than the threshold voltage (1.2V) of the transistors M_{A}~M_{J}, and lower than the stress voltage (8V) of the transistors M_{A}~M_{J}.

As shown in FIG. 5D, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the second supply voltage V_{SS}. That is, the inverted level shifted signal LS_{1B} is equal to the second supply voltage V_{SS}. Furthermore, the transistor M_{A} is turned on, and the transistor M_{C} is turned off. The voltage at the node a is equal to the second output voltage V_{OUT2} (i.e., R×V_{S1}). That is, the level shifted signal LS₁ is equal to the second output voltage V_{OUT2} (i.e., R×V_{S1}). Consequently, the transistor M_{D} is turned on, and the transistor M_{B} is turned off. Furthermore, the voltage at the node d is approximately equal to (V_{S1}-V_{THJ}), wherein V_{THJ} is the threshold voltage of the transistor M_{J}. For example, the threshold voltage V_{THJ}is 1.2V.

As can be seen from FIGS. 5C and 5D, when the non-volatile memory is in the first transition phase PH_{T}₁, the voltages outputted from the level shifters 421 and 422 of the driving voltage supplying circuit 400 are lower than the erase voltage V_{EE}. Furthermore, the voltage difference between the high power voltage V_{H} and the low power voltage V_{L} is equal to (R×V_{S1}-V_{SS}). Since each of the transistors M_{A}~M_{J} in the level shifter 421 can withstand the stress voltage, all transistors M_{A}~M_{J} can be operated in the safe operating area (SOA).

Please refer to FIGS. 5B, 5E and 5F. The time interval between the time point t_{B} and the time point t_{C} is the second transition phase PH_{T}₂. The controlling circuit 418 provides the voltage setting signal S_{SET} to control the first charge pump 412 to generate the second set voltage V_{S}₂. That is, the first output voltage V_{OUT1}is equal to the second set voltage V_{S}₂. In the second transition phase PH_{T}₂, the controlling circuit 418 does not activate the enable signal EN2. Consequently, the second output voltage V_{OUT2} outputted from the second charge pump 414 is maintained at the product of the ratio value R and the first set voltage V_{S}₁ (R×V_{S1}). Furthermore, the controlling circuit 418 provides the switching signal SW to the switching circuit 216. According to the switching signal SW, the switching circuit 216 generates the switching output voltage V_{SW}. The switching output voltage V_{SW} is equal to the first output voltage V_{OUT1}, i.e., the second set voltage V_{S}₂. In other words, the high voltage power supply terminals of the level shifters 421 and 422 receive the second output voltage V_{OUT2} (R×V_{S1}). The low voltage power supply terminals of the level shifters 421 and 422 receive the second set voltage V_{S}₂. The bias terminals of the level shifters 421 and 422 receive the second set voltage V_{S}₂. For example, the second set voltage V_{S}₂is 6.25V. Consequently, the high power voltage V_{H} is 7.77V (1.85×4.2V), the bias voltage V_{BIAS} is 6.25V, and the low power voltage V_{L} is 6.25V. Obviously, the voltage difference (1.52V) between the high power voltage V_{H} and the low power voltage V_{L} is higher than the threshold voltage (1.2V) of the transistors M_{A}~M_{J}, and lower than the stress voltage (8V) of the transistors M_{A}~M_{J}.

As shown in FIG. 5F, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the second set voltage V_{S}₂. That is, the inverted level shifted signal LS_{1B} is equal to the second set voltage V_{S}₂. Furthermore, the transistor M_{A} is turned on, and the transistor M_{C} is turned off. The voltage at the node a is equal to the second output voltage V_{OUT2} (i.e., R×V_{S1}). That is, the level shifted signal LS₁ is equal to the second output voltage V_{OUT2} (i.e., R×V_{S1}). Consequently, the transistor M_{D} is turned on, and the transistor M_{B} is turned off.

As can be seen from FIGS. 5E and 5F, when the non-volatile memory is in the second transition phase PH_{T}₂, the voltages outputted from the level shifters 421 and 422 of the driving voltage supplying circuit 400 are lower than the erase voltage V_{EE}. Furthermore, the voltage difference between the high power voltage V_{H} and the low power voltage V_{L} is equal to (R×V_{S1}-V_{S}₂). Since each of the transistors M_{A}~M_{J} in the level shifter 421 can withstand the stress voltage, all transistors M_{A}~M_{J} can be operated in the safe operating area (SOA).

Please refer to FIGS. 5B, 5G and 5H. The time interval between the time point t_{C} and the time point t_{D} is the third transition phase PH_{T}₃. The controlling circuit 418 provides the voltage setting signal S_{SET} to control the first charge pump 412 to generate the second set voltage V_{S}₂. That is, the first output voltage V_{OUT1}is equal to the second set voltage V_{S}₂. In the third transition phase PH_{T}₃, the controlling circuit 418 activates the enable signal EN2. Consequently, the second output voltage V_{OUT2} outputted from the second charge pump 414 is equal to the product of the ratio value R and the second set voltage V_{S}₂ (R×V_{S}₂). Furthermore, the controlling circuit 418 provides the switching signal SW to the switching circuit 216. According to the switching signal SW, the switching circuit 216 generates the switching output voltage V_{SW}. The switching output voltage V_{SW} is equal to the first output voltage V_{OUT1}, i.e., the second set voltage V_{S}₂. In other words, the high voltage power supply terminals of the level shifters 421 and 422 receive the second output voltage V_{OUT2} (R×V_{S}₂). The low voltage power supply terminals of the level shifters 421 and 422 receive the second set voltage V_{S}₂. The bias terminals of the level shifters 421 and 422 receive the second set voltage V_{S}₂. For example, the second set voltage V_{S}₂is 6.25V. Consequently, the high power voltage V_{H} is 11.56V (1.85×6.25V), the bias voltage V_{BIAS} is 6.25V, and the low power voltage V_{L} is 6.25V. Obviously, the voltage difference (5.31V) between the high power voltage V_{H} and the low power voltage V_{L} is higher than the threshold voltage (1.2V) of the transistors M_{A}~M_{J}, and lower than the stress voltage (8V) of the transistors M_{A}~M_{J}.

As shown in FIG. 5H, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the second set voltage V_{S}₂. That is, the inverted level shifted signal LS_{1B} is equal to the second set voltage V_{S}₂. Furthermore, the transistor M_{A} is turned on, and the transistor M_{C} is turned off. The voltage at the node a is equal to the second output voltage V_{OUT2} (i.e., R×V_{S}₂). That is, the level shifted signal LS₁ is equal to the second output voltage V_{OUT2} (i.e., R×V_{S}₂). Consequently, the transistor M_{D} is turned on, and the transistor M_{B} is turned off.

As can be seen from FIGS. 5G and 5H, when the non-volatile memory is in the third transition phase PH_{T}₃, the voltages outputted from the level shifters 421 and 422 of the driving voltage supplying circuit 400 are lower than the erase voltage V_{EE}. Furthermore, the voltage difference between the high power voltage V_{H} and the low power voltage V_{L} is equal to (R×V_{S1}-V_{S}₂). Since each of the transistors M_{A}~M_{J} in the level shifter 421 can withstand the stress voltage, all transistors M_{A}~M_{J} can be operated in the safe operating area (SOA).

Please refer to FIGS. 5B, 5I and 5J. The time interval between the time point t_{D} and the time point t_{E} is the fourth transition phase PH_{T}₄. The controlling circuit 418 provides the voltage setting signal S_{SET} to control the first charge pump 412 to generate the program voltage V_{PP}. The program voltage V_{PP}is higher than the second set voltage V_{S}₂. That is, the first output voltage V_{OUT1} is equal to the program voltage V_{PP}. In the fourth transition phase PH_{T}₄, the controlling circuit 418 does not activate the enable signal EN2. Consequently, the second output voltage V_{OUT2} outputted from the second charge pump 414 is maintained at the product of the ratio value R and the second set voltage V_{S}₂ (R×V_{S}₂). Furthermore, the controlling circuit 418 provides the switching signal SW to the switching circuit 216. According to the switching signal SW, the switching circuit 216 generates the switching output voltage V_{SW}. The switching output voltage V_{SW} is equal to the first output voltage V_{OUT1}, i.e., the program voltage V_{PP}. In other words, the high voltage power supply terminals of the level shifters 421 and 422 receive the second output voltage V_{OUT2} (R×V_{S}₂). The low voltage power supply terminals of the level shifters 421 and 422 receive the program voltage V_{PP}. The bias terminals of the level shifters 421 and 422 receive the program voltage V_{PP}. For example, the program voltage V_{PP}is 7.5V. Consequently, the high power voltage V_{H} is 11.56V (1.85×6.25V), the bias voltage V_{BIAS} is 7.5V, and the low power voltage V_{L} is 7.5V. Obviously, the voltage difference (4.06V) between the high power voltage V_{H} and the low power voltage V_{L} is higher than the threshold voltage (1.2V) of the transistors M_{A}~M_{J}, and lower than the stress voltage (8V) of the transistors M_{A}~M_{J}.

As shown in FIG. 5J, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the program voltage V_{PP}. That is, the inverted level shifted signal LS_{1B} is equal to the program voltage V_{PP}. Furthermore, the transistor M_{A} is turned on, and the transistor M_{C} is turned off. The voltage at the node a is equal to the second output voltage V_{OUT2} (i.e., R×V_{S}₂). That is, the level shifted signal LS₁ is equal to the second output voltage V_{OUT2} (i.e., R×V_{S}₂). Consequently, the transistor M_{D} is turned on, and the transistor M_{B} is turned off.

As can be seen from FIGS. 5I and 5J, when the non-volatile memory is in the fourth transition phase PH_{T}₄, the voltages outputted from the level shifters 421 and 422 of the driving voltage supplying circuit 400 are lower than the erase voltage V_{EE}. Furthermore, the voltage difference between the high power voltage V_{H} and the low power voltage V_{L} is equal to (R×V_{S1}-V_{PP}). Since each of the transistors M_{A}~M_{J} in the level shifter 421 can withstand the stress voltage, all transistors M_{A}~M_{J} can be operated in the safe operating area (SOA).

Please refer to FIGS. 5B, 5K and 5L. The time interval after the time point t_{E} is the erase phase PH_{ERS}. The controlling circuit 418 provides the voltage setting signal S_{SET} to control the first charge pump 412 to generate the program voltage V_{PP}. The program voltage V_{PP}is higher than the second set voltage V_{S}₂. That is, the first output voltage V_{OUT1} is equal to the program voltage V_{PP}. In the erase phase PH_{ERS}, the controlling circuit 418 activates the enable signal EN2. Consequently, the second output voltage V_{OUT2} outputted from the second charge pump 414 is equal to the product of the ratio value R and the program voltage V_{PP} (R× V_{PP}). That is, the second output voltage V_{OUT2} is equal to the erase voltage V_{EE}. Furthermore, the controlling circuit 418 provides the switching signal SW to the switching circuit 216. According to the switching signal SW, the switching circuit 216 generates the switching output voltage V_{SW}. The switching output voltage V_{SW} is equal to the first output voltage V_{OUT1}, i.e., the program voltage V_{PP}. In other words, the high voltage power supply terminals of the level shifters 421 and 422 receive the second output voltage V_{OUT2}, and the second output voltage V_{OUT2} is equal to the erase voltage V_{EE}. The low voltage power supply terminals of the level shifters 421 and 422 receive the program voltage V_{PP}. The bias terminals of the level shifters 421 and 422 receive the program voltage V_{PP}. For example, the program voltage V_{PP}is 7.5V. Consequently, the high power voltage V_{H} is 13.875V (1.85×7.5V), the bias voltage V_{BIAS} is 7.5V, and the low power voltage V_{L} is 7.5V. Obviously, the voltage difference (6.38V) between the high power voltage V_{H} and the low power voltage V_{L} is higher than the threshold voltage (1.2V) of the transistors M_{A}~M_{J}, and lower than the stress voltage (8V) of the transistors M_{A}~M_{J}.

As shown in FIG. 5L, the control signal C_{IN1} is the logic high level (Hi), and the inverted control signal C_{IN1B} is the logic low level (Lo). The transistors M_{E} and M_{G} are turned on, and the transistor M_{H} is turned off. The voltage at each of the nodes b and c is equal to the program voltage V_{PP}. That is, the inverted level shifted signal LS_{1B} is equal to the program voltage V_{PP}. Furthermore, the transistor M_{A} is turned on, and the transistor M_{C} is turned off. The voltage at the node a is equal to the erase voltage V_{EE}. That is, the level shifted signal LS₁ is equal to the erase voltage V_{EE}. Consequently, the transistor M_{D} is turned on, and the transistor M_{B} is turned off.

As can be seen from FIGS. 5K and 5L, when the non-volatile memory is in the erase phase PH_{ERS}, the voltages outputted from the level shifters 421 and 422 of the driving voltage supplying circuit 400 reach the erase voltage V_{EE}. Furthermore, the voltage difference between the high power voltage V_{H} and the low power voltage V_{L} is equal to (V_{EE}-V_{PP}). Since each of the transistors M_{A}~M_{J} in the level shifter 421 can withstand the stress voltage, all transistors M_{A}~M_{J} can be operated in the safe operating area (SOA).

Furthermore, in the transition phases PH₁~PH₄ and the erase phase PH_{ERS}, if the control signal C_{IN1} is continuously maintained in the the logic high level (Hi), the waveform change of the level shifted signal LS₁ will be the same as the waveform change of the high power supply voltage V_{H}. Whereas, if the control signal C_{IN1} is continuously maintained in the logic low level (Lo), the waveform change of the level shifted signal LS₁ will be the same as the waveform change of the low power supply voltage V_{L}. In other words, after the time point t_{F}, the non-volatile memory can start the erase action.

For example, when the erase action is performed, the control signal C_{IN1} is the logic high level (Hi), and the control signal C_{IN}₂ is the logic low level (Lo). Consequently, the level shifted signal LS₁ from the level shifter 421 is the erase voltage V_{EE}, and the level shifted signal LS₂ from the level shifter 422 is the program voltage V_{PP}. That is, in the memory cell array, the erase line EL₁ receives the erase voltage V_{EE}, and the erase line EL₂ receives the program voltage V_{PP} that is lower than the erase voltage V_{EE}. Consequently, in the memory cell array, all memory cells in the first sector become the erased state, and the storage states of the memory cells in the second sector are kept unchanged.

As can be seen from FIGS. 5C and 5J, when the non-volatile memory is in the transition phases PH₁~PH₄, the power circuit 410 adjusts the first output voltage V_{OUT1}, the second output voltage V_{OUT2} and the switching output voltage V_{SW}. Furthermore, under control of the power circuit 410, the high power voltage V_{H} received by the level shifters 421 and 422 is higher than the low power voltage V_{L}, and the high power voltage V_{H} minus the low power voltage V_{L} is lower than or equal to the stress voltage. Consequently, all transistors M_{A}~M_{J} can be operated normally without being damaged.

It is noted that the circuitry structure of the driving voltage supplying circuit is not restricted to the circuitry structure of the driving voltage supplying circuit 200 and the circuitry structure of the driving voltage supplying circuit 400. That is, the circuitry structure of the driving voltage supplying circuit may be altered according to the practical requirements. For example, in a third embodiment, the driving voltage supplying circuit power circuit includes the power circuit 210 of the first embodiment and the level shifters 421 and 422 of the second embodiment. Similarly, in a fourth embodiment, the driving voltage supplying circuit power includes the level shifters 221 and 222 of the first embodiment and the power circuit 410 of the second embodiment.

From the above descriptions, the present invention provides a driving voltage supplying circuit for a non-volatile memory. The charge pump is used to generate the erase voltage, and the level shifters are used to transmit the erase voltage. When the non-volatile memory performs the erase action, the level shifters provides the erase voltage to the memory cell array. The present invention further provides a control method for the driving voltage supplying circuit in order to assure that all transistors in the level shifters to be operated in the safe operating area (SOA).

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A driving voltage supplying circuit coupled to a memory cell array of a non-volatile memory, the memory cell array comprising a first sector and a second sector, all memory cells in the first sector being connected with a first erase line, all memory cells in the second sector being connected with a second erase line, the driving voltage supplying circuit comprising:
a power circuit receiving a first supply voltage and a second supply voltage, wherein a first output terminal of the power circuit outputs a first output voltage, a second output terminal of the power circuit outputs a second output voltage, and a third output terminal of the power circuit outputs a switching output voltage; and
a first level shifter, wherein a high power voltage terminal of the first level shifter is connected with the second output terminal of the power circuit to receive the second output voltage, and the second output voltage is a high power voltage of the first level shifter, wherein a bias terminal of the first level shifter is connected with the first output terminal of the power circuit to receive the first output voltage, and the first output voltage is a bias voltage of the first level shifter, wherein a low power voltage terminal of the first level shifter is connected with the third output terminal of the power circuit to receive the switching output voltage, and the switching output voltage is a low power voltage of the first level shifter, wherein an input terminal of the first level shifter receives a first control signal, wherein an output terminal of the first level shifter outputs a first level shifted signal, and the output terminal of the first level shifter is coupled to the first erase line;
wherein when an erase action is not performed by the non-volatile memory, the first output voltage of the power circuit is the first supply voltage, the second output voltage is the first supply voltage, and the switching output voltage is the second supply voltage,
wherein when the non-volatile memory is in a first transition phase, the first output voltage, the second output voltage and the switching output voltage are adjusted by the power circuit,
wherein the non-volatile memory enters an erase phase after the first transition phase, wherein in the erase phase, the first output voltage is adjusted to a program voltage, the second output voltage is increased to an erase voltage, and the switching output voltage is increased to the program voltage,
wherein the erase voltage is higher than the program voltage, the program voltage is higher than the first supply voltage, and the first supply voltage is higher than the second supply voltage.

2. The driving voltage supplying circuit as claimed in claim 1, wherein when the non-volatile memory is in the erase phase and the first control signal is in a logic high level, the erase voltage is transmitted from the output terminal of the first level shifter to the first erase line, and the erase action is performed on all memory cells in the first sector, so that all memory cells in the first sectors are in an erased state.

3. The driving voltage supplying circuit as claimed in claim 1, wherein in the first transition phase, the first output voltage, the second output voltage and the switching output voltage are adjusted by the power circuit, so that the high power voltage is higher than the low power voltage, wherein a voltage difference between the high power voltage and the low power voltage is lower than a stress voltage of each of the plurality of transistors.

4. The driving voltage supplying circuit as claimed in claim 3, wherein the power circuit comprises:
a control circuit generating a first enable signal, a second enable signal and a switching signal;
a first charge pump receiving the first supply voltage and the first enable signal, wherein when the first enable signal is not activated, the first charge pump generates the first output voltage, and the first output voltage is equal to the first supply voltage, wherein when the first enable signal is activated, the first charge pump boosts the first output voltage from the first supply voltage to the program voltage;
a second charge pump receiving the first output voltage and responsive to at least the second enable signal, wherein when the second enable signal is not activated, the second charge pump provides a conductive path such that the second output voltage is substantially equal to the first output voltage, wherein when the second enable signal is activated, the second charge pump boosts the second output voltage from the first output voltage to the erase voltage; and
a switching circuit receiving the second supply voltage, the first output voltage and the switching signal, wherein the switching circuit generates the switching output voltage according to the switching signal, and the switching output voltage is one of the second supply voltage and the first output voltage.

5. The driving voltage supplying circuit as claimed in claim 4, wherein when the erase action is not performed, the first enable signal and the second enable signal are not activated, the first output voltage is the first supply voltage, the second output voltage is the first supply voltage, and the switching circuit selects the second supply voltage as the switching output voltage.

6. The driving voltage supplying circuit as claimed in claim 5, wherein in the first transition phase, the first enable signal is activated, the second enable signal is not activated, the first output voltage is the program voltage, and the second output voltage is the program voltage, and the switching circuit selects the second supply voltage as the switching output voltage.

7. The driving voltage supplying circuit as claimed in claim 6, wherein in the erase phase, the first enable signal and the second enable signal are activated, the first output voltage is the program voltage, the second output voltage is the erase voltage, and the switching circuit selects the program voltage as the switching output voltage.

8. The driving voltage supplying circuit as claimed in claim 1, wherein the first level shifter comprises:
a first transistor, wherein a first drain/source terminal of the first transistor receives the high power voltage, a second drain/source terminal of the first transistor is connected with a first node, and a gate terminal of the first transistor is connected with a second node, wherein the first node is the output terminal of the first level shifter, and the output terminal of the first level shifter is coupled to the first erase line;
a second transistor, wherein a first drain/source terminal of the second transistor receives the high power voltage, a second drain/source terminal of the second transistor is connected with the second node, and a gate terminal of the second transistor is connected with the first node;
a third transistor, wherein a first drain/source terminal of the third transistor is connected with the first node, a second drain/source terminal of the third transistor receives the lower power voltage, and a gate terminal of the third transistor is connected with the second node;
a fourth transistor, wherein a first drain/source terminal of the fourth transistor is connected with the second node, a second drain/source terminal of the fourth transistor receives the lower power voltage, and a gate terminal of the fourth transistor is connected with the first node;
a fifth transistor, wherein a first drain/source terminal of the fifth transistor is connected with the second node, a second drain/source terminal of the fifth transistor is connected with a third node, and a gate terminal of the fifth transistor receives the bias voltage;
a sixth transistor, wherein a first drain/source terminal of the sixth transistor is connected with the first node, a second drain/source terminal of the sixth transistor is connected with a fourth node, and a gate terminal of the sixth transistor receives the bias voltage;
a seventh transistor, wherein a first drain/source terminal of the seventh transistor is connected with the third node, a second drain/source terminal of the seventh transistor receives the low power voltage, and a gate terminal of the seventh transistor receives the first control signal; and
an eighth transistor, wherein a first drain/source terminal of the eighth transistor is connected with the fourth node, a second drain/source terminal of the eighth transistor receives the low power voltage, and a gate terminal of the eighth transistor receives an inverted first control signal.

9. The driving voltage supplying circuit as claimed in claim 8, wherein the first level shifter further comprises a ninth transistor and a tenth transistor, wherein a first drain/source terminal of the ninth transistor is connected with the third node, a second drain/source terminal of the ninth transistor receives the bias voltage, and a gate terminal of the ninth transistor is connected with the third node, wherein a first drain/source terminal of the tenth transistor is connected with the fourth node, a second drain/source terminal of the tenth transistor receives the bias voltage, and a gate terminal of the tenth transistor is connected with the fourth node.

10. The driving voltage supplying circuit as claimed in claim 1, wherein after the first transition phase, the non-volatile memory is in a plurality of additional transition phases successively, wherein in the first transition phase and the plurality of additional transition phases, the first output voltage, the second output voltage and the switching output voltage are adjusted by the power circuit, so that the high power voltage is higher than the low power voltage, wherein a voltage difference between the high power voltage and the low power voltage is higher than a threshold voltage of each of the plurality of transistors, and the voltage difference between the high power voltage and the low power voltage is lower than a stress voltage of each of the plurality of transistors.

11. The driving voltage supplying circuit as claimed in claim 10, wherein the power circuit comprises:
a first control circuit generating a voltage setting signal, an enable signal and a switching signal;
a first charge pump receiving the first supply voltage and the voltage setting signal, wherein the first charge pump generates the first output voltage according to the voltage setting signal, wherein the first output voltage is higher than or equal to the first supply voltage;
a second charge pump receiving the first output voltage and the enable signal, wherein when the enable signal is activated, the second output voltage generated by the second charge pump is equal to a product of the first output voltage and a ratio value, and the ratio value is greater than 1, wherein when the enable signal is not activated, the second output voltage generated by the second charge pump is kept unchanged; and
a switching circuit receiving the second supply voltage, the first output voltage and the switching signal, wherein the switching circuit generates the switching output voltage according to the switching signal, and the switching output voltage is one of the second supply voltage and the first output voltage;
wherein the first level shifter includes a plurality of transistors, each of the transistors having a threshold voltage and capable of withstanding a stress voltage;
wherein the first output voltage is set, such that a first voltage difference between the second output voltage and the switching output voltage is less than or equal to a second voltage difference between the stress voltage and the threshold voltage.

12. The driving voltage supplying circuit as claimed in claim 11, wherein when the erase action is not performed by the non-volatile memory, the first output voltage generated by the first charge pump is controlled to be the first supply voltage according to the voltage setting signal, the enable signal is not activated, the second output voltage is the first supply voltage, and the switching output voltage is the second supply voltage.

13. The driving voltage supplying circuit as claimed in claim 12, wherein when the non-volatile memory is in the first transition phase, the first output voltage generated by the first charge pump is controlled to be a first set voltage according to the voltage setting signal, the enable signal is activated, the second output voltage is equal to a product of the first set voltage and the ratio value, and the switching circuit selects the second supply voltage as the switching output voltage, wherein the first set voltage is higher than the first supply voltage.

14. The driving voltage supplying circuit as claimed in claim 13, wherein the non-volatile memory enters a second transition phase after the first transition phase, wherein in the second transition phase, the first output voltage generated by the first charge pump is controlled to be a second set voltage according to the voltage setting signal, the enable signal is not activated, the second output voltage is equal to the product of the first set voltage and the ratio value, and the switching circuit selects the first output voltage as the switching output voltage, wherein the second set voltage is higher than the first set voltage.

15. The driving voltage supplying circuit as claimed in claim 14, wherein the non-volatile memory enters a third transition phase after the second transition phase, wherein in the third transition phase, the first output voltage generated by the first charge pump is controlled to be the second set voltage according to the voltage setting signal, the enable signal is activated, the second output voltage is equal to a product of the second set voltage and the ratio value, and the switching circuit selects the first output voltage as the switching output voltage.

16. The driving voltage supplying circuit as claimed in claim 15, wherein the non-volatile memory enters a fourth transition phase after the third transition phase, wherein in the fourth transition phase, the first output voltage generated by the first charge pump is controlled to be the program voltage according to the voltage setting signal, the enable signal is not activated, the second output voltage is equal to the product of the second set voltage and the ratio value, and the switching circuit selects the first output voltage as the switching output voltage, wherein the program voltage is higher than the second set voltage.

17. The driving voltage supplying circuit as claimed in claim 16, wherein the non-volatile memory enters the erase phase after the fourth transition phase, wherein in the erase phase, the first output voltage generated by the first charge pump is controlled to be the program voltage according to the voltage setting signal, the enable signal is activated, the second output voltage is equal to a product of the program voltage and the ratio value, and the switching circuit selects the first output voltage as the switching output voltage, wherein the product of the program voltage and the ratio value is equal to the erase voltage.

18. The driving voltage supplying circuit as claimed in claim 1, wherein the driving voltage supplying circuit further comprises a second level shifter, wherein a high power voltage terminal of the second level shifter is connected with the second output terminal of the power circuit to receive the second output voltage, and the second output voltage is a high power voltage of the second level shifter, wherein a bias terminal of the second level shifter is connected with the first output terminal of the power circuit to receive the first output voltage, and the first output voltage is a bias voltage of the second level shifter, wherein a low power voltage terminal of the second level shifter is connected with the third output terminal of the power circuit to receive the switching output voltage, and the switching output voltage is a low power voltage of the second level shifter, wherein an input terminal of the second level shifter receives a second control signal, an output terminal of the second level shifter outputs a second level shifted signal, and the output terminal of the second level shifter is coupled to the second erased line.
